(19) United States
(12) Patent Application Publication
(10) Pub. No.: US 2014/0114592 A1
(43) Pub. Date: Apr. 24, 2014

(54) OPERATIONAL MONITORING OF ELECTROCHEMICAL CAPACITORS

(71) Applicant: Custom Electronics, Inc., Oneonta, NY (US)

(72) Inventor: Thor E. Eilertsen, Oneonta, NY (US)

(73) Assignee: Custom Electronics, Inc., Oneonta, NY (US)

(21) Appl. No.: 14/059,845

(22) Filed: Oct. 22, 2013

Related U.S. Application Data
(60) Provisional application No. 61/716,782, filed on Oct. 22, 2012.

(51) Int. Cl. G01R 31/36

(52) U.S. Cl. CPC G01R 31/3606
USPC 702/58; 324/548

(57) ABSTRACT

The invention provides operational monitoring for electrochemical capacitors and, more specifically, the monitoring of operational performance characteristics of electrochemical capacitors using electrochemical impedance measurement in an application system in the field. The apparatus and methods of the present invention monitor the operational characteristics of a plurality of electrochemical capacitors in an application system with the goal of providing state of health information to the application system or through another monitoring or alert system. By generating an input monitoring signal to query each cell in the pack and calculating the impedance measurement signal from the resulting output signal, the real-time impedance measurements can be compared against a stored electrochemical impedance model to provide state of health information. Real-time monitoring data based on the state of health information can then be output to the application system or through another monitoring or alert system.

### RELATED APPLICATIONS

This application claims priority from U.S. Provisional Patent Application No. 61/716,782 filed Oct. 22, 2012 and titled “Electrochemical Energy Performance Monitoring System”.

### FIELD

The invention relates to the field of electrochemical capacitors and, more specifically, the monitoring of operational performance characteristics of electrochemical capacitors in an application system in the field.

### BACKGROUND

Electrochemical capacitors are well known in the art have been used in energy storage, transfer, and conditioning applications since the early 20^{th} century. The most common electrochemical capacitors are electrolytic capacitors and electric double-layer capacitors (ELDCs, also known as supercapacitors or ultracapacitors).

Electrochemical capacitors are generally manufactured as flat rectangular prismatic cells or rolled cylindrical cells in an insulated canister with exposed positive and negative leads for integration into a larger system. A number of these individual electrochemical capacitor cells are then placed in a larger package and electrically connected into an integrated module with the desired characteristics for specific applications in the field, referred to as a pack. For example, an energy storage pack for use in large windmill pitch control might contain 34 individual ultracapacitor cells connected in series to provide a pack with a single set of leads, a nominal capacitance of 76.5 F and a nominal voltage of 76 VDC.

Some electrochemical capacitor packs may also include onboard electronics for carrying out specialized functions related to the application system for which they are designed. These electronics go beyond the wiring necessary to electrically connect the cells and provide leads to the application system. For example, an energy storage pack for emergency motor control could integrate a motor controller into the onboard electronics or a heat sensitive application system could include a temperature sensor and logic for evaluating temperature conditions. Advanced packs may include a microprocessor or microcontroller, data storage, and system memory to enable programmable features.

While electrochemical capacitors are generally regarded as more reliable than batteries for many applications, they are still not 100% reliable. Use, environment, and minor manufacturing defects can impact the performance of electrochemical capacitors and, over time, lead to decreased efficiency and potential failure in application systems in the field. The risk increases as more and more electrochemical capacitor packs are deployed in remote and/or mission critical applications.

The desire to monitor energy storage packs is well known. Nearly every portable device includes a battery monitor that at least tracks state of charge and may track capacity decay over time. The current state of energy stored in an energy storage pack may be referred to as State of Charge (SOC) and the ability of the device to receive, retain, and release a charge may be referred to as State of Health (SOH). Packs for energy transfer and conditioning applications have parallel states that describe their charge-state and performance-state.

Electric cars and energy storage for critical applications (exploration, military, communications, power generation) have increased the interest in real-time performance monitoring with the goals of predictive maintenance and active management for system efficiency. Complex monitoring systems have been developed for battery packs and application systems using such battery packs. Commercial monitoring of systems in use today makes primary use of direct current and voltage measurement to help determine SOH. In order for the more sophisticated SOH monitoring to work it is necessary for the energy storage system to be incapacitated. Especially battery systems, because in order to determine a rate of charge and charge capacity, the battery storage unit must be fully discharged and fully recharged in that sequence while off line. The existing techniques used for battery packs may not provide the desired SOH information for electrochemical capacitors and the requirement that diagnostics take the pack offline to achieve a fully discharged state is not feasible for real-time monitoring in the field.

Extensive use of impedance spectroscopy has been utilized in the laboratory for determining fundamental characteristics of electrochemical cells. Electrochemical impedance spectroscopy or EIS, can be implemented through the use of instrumentation that has only been computerized in the last 20 years. EIS has been known for over a century, but the augmentation of electronics and computer firmware has been necessary for automated laboratory testing using EIS to be accomplished.

Fundamental investigations of the impedance yield a wealth of information about different molecular motions and relaxation processes. The use of electrical perturbation quantities allows a kinetic study to be done, which permits dissection of the couplings between elementary phenomena by control of the reaction rates. This enables the mono-electronic steps in the reaction mechanisms to be distinguished and the often unstable reaction intermediates involved in these reactions to be tabulated into a memory array for later processing. If these techniques do not allow a real identification of the bonds and the reaction intermediates from a chemical point of view, they still give information on the kinetics of the reaction mechanism governing the behavior of the electrochemical interface and some characterization of these intermediates. Non-steady state techniques are necessary for investigating complex electrochemical systems. The use of these techniques rests on principles analogous to those which justify relaxation methods employed at equilibrium state in chemical kinetics. Disturbing the reaction from the steady-state by applying a perturbation to the electrochemical system allows the system to relax to a new steady-state. As the various elementary processes change at different rates, the response can be analyzed to dissect the overall electrochemical process, providing over time an aging history.

EIS technology is very useful for determining many of the performance characteristics of energy storage and power devices such as batteries, capacitors and fuel cells. In a laboratory this is normally accomplished in a dry box using a 3 electrode cell configuration. The test cell has a working electrode in conjunction with a reference electrode. The third electrode is the counter electrode and is considered very large or having a near infinite capacity so as not to influence the actual tests of interest undergoing at the working electrode. Testing of interest takes place at the working and reference electrodes where information can be derived from the electrode bulk and or the electrode—electrolyte interface. In some cases when a complete cell, in its manufactured form factor, is tested there are only two terminals available and more creative wiring schemes are required. However, these bench tests require that individual cells be removed from their application system for analysis by EIS. Additionally, full frequency scans and analysis of the resulting signal data can create data storage and processing overhead that may not be practical for cost-effective real-time monitoring of individual cells in an integrated pack in an application system in the field.

### SUMMARY

### Technical Problem

Current systems for monitoring electrochemical capacitors are inadequate for real-time state of health monitoring of cells deployed in operating application systems. Systems and methods for using electrochemical impedance spectroscopy to monitor the operational state of health of electrochemical capacitor cells in their application systems in real-time in the field are needed. Additionally, there is a lack of on-board monitoring and testing capabilities in integrated packs of electrochemical cells, which could improve manufacturing, integration, and repair efficiency in the production and maintenance of complex application systems.

### Solution to Problem

The present invention provides operational monitoring for electrochemical capacitors and, more specifically, the monitoring of operational performance characteristics of electrochemical capacitors using electrochemical impedance measurement in an application system in the field. The apparatus and methods of the present invention monitor the operational characteristics of a plurality of electrochemical capacitors in an application system with the goal of providing state of health information to the application system or through another monitoring or alert system. By generating an input monitoring signal to query each cell in the pack and calculating the impedance measurement signal from the resulting output signal, the real-time impedance measurements can be compared against a stored electrochemical impedance model to provide state of health information. Real-time monitoring data based on the state of health information can then be output to the application system or through another monitoring or alert system.

One embodiment is an apparatus for monitoring operational characteristics of a plurality of capacitors in an application system. A monitoring signal generator generates an input monitoring signal for each of the plurality of capacitors. A measurement module receives an output monitoring signal for each of the plurality of capacitors in response to the input monitoring signal and generates a measurement signal representing an impedance differential between the input monitoring signal and the output monitoring signal. The apparatus compares an electrochemical impedance model for the plurality of capacitors to the measurement signal to determine a state of health. A monitoring module generates and outputs real-time monitoring data correlating to the state of health for the plurality of capacitors from the measurement signal and the electrochemical impedance model.

Another embodiment is a method for monitoring operational characteristics of a plurality of capacitors in an application system. An input monitoring signal is generated for each of the plurality of capacitors. An output monitoring signal is received for each of the plurality of capacitors in response to the input monitoring signal. A measurement signal is generated by calculating an impedance differential between the input monitoring signal and the output monitoring signal. Real-time monitoring data is generated by comparing the impedance differential to an electrochemical impedance model for the plurality of capacitors to determine a state of health of the plurality of capacitors. The real-time monitoring data correlating to the state of health for the plurality of capacitors is output.

Another embodiment is an energy storage pack including a plurality of capacitors, a monitoring signal generator, a measurement module, an electrochemical impedance model, and a monitoring module. The monitoring signal generator generates an input monitoring signal for each of the plurality of capacitors. The measurement module receives an output monitoring signal for each of the plurality of capacitors in response to the input monitoring signal and generates a measurement signal representing an impedance differential between the input monitoring signal and the output monitoring signal. The measurement signal is compared to the electrochemical impedance model to determine a state of health. The monitoring module generates and outputs real-time monitoring data correlating to the state of health for the plurality of capacitors from the measurement signal and the electrochemical impedance model.

### Advantageous Effects of Invention

The present invention provides real-time monitoring of operating performance characteristics of a plurality of electrochemical capacitors in an application system. Use of electrochemical impedance measurement provides accurate state of health information and use of an electrochemical impedance model makes such measurement and calculation practical while limiting processing and data storage overhead. The efficiency of the monitoring apparatus and methods enables integration into energy storage packs for improved manufacturing, integration, and repair efficiency in the production and maintenance of complex application systems.

### BRIEF DESCRIPTION OF DRAWINGS

FIG. 1

A block diagram of an apparatus for monitoring capacitors.

FIG. 2

A block diagram of capacitors connected to the interface modules of an apparatus for monitoring the capacitors, such as the apparatus of FIG. 1.

FIG. 3

A block diagram of an energy storage pack incorporating an apparatus for monitoring capacitors, such as the apparatus of FIG. 1, and capacitors and which is connected to an application system.

FIG. 4

A flow chart of operational monitoring of capacitors using electrochemical impedance, such as could be implemented by the apparatus of FIG. 1.

FIG. 5

A flow chart of a process for generating and outputting real-time monitoring data for operational monitoring, such as the operational monitoring of FIG. 4.

FIG. 6

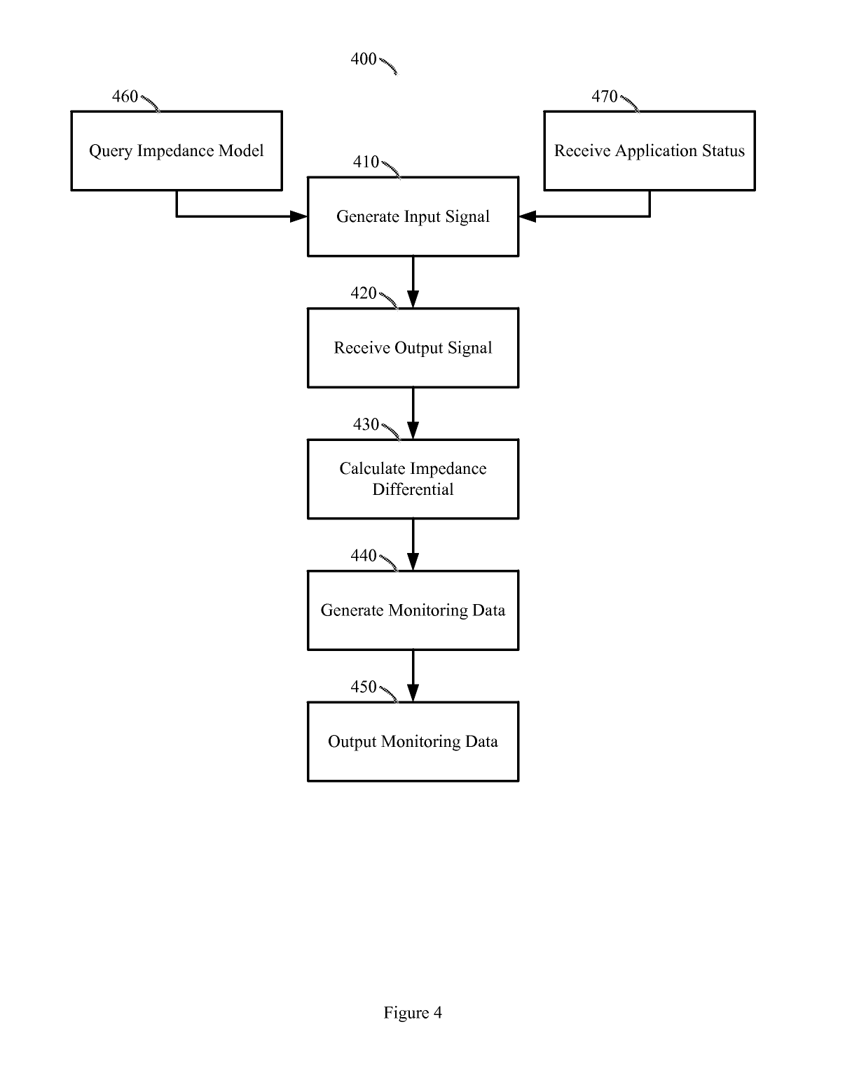

A flow chart of data and processing for operational monitoring of capacitors, such as the operational monitoring of FIG. 4.

### DESCRIPTION OF EMBODIMENTS

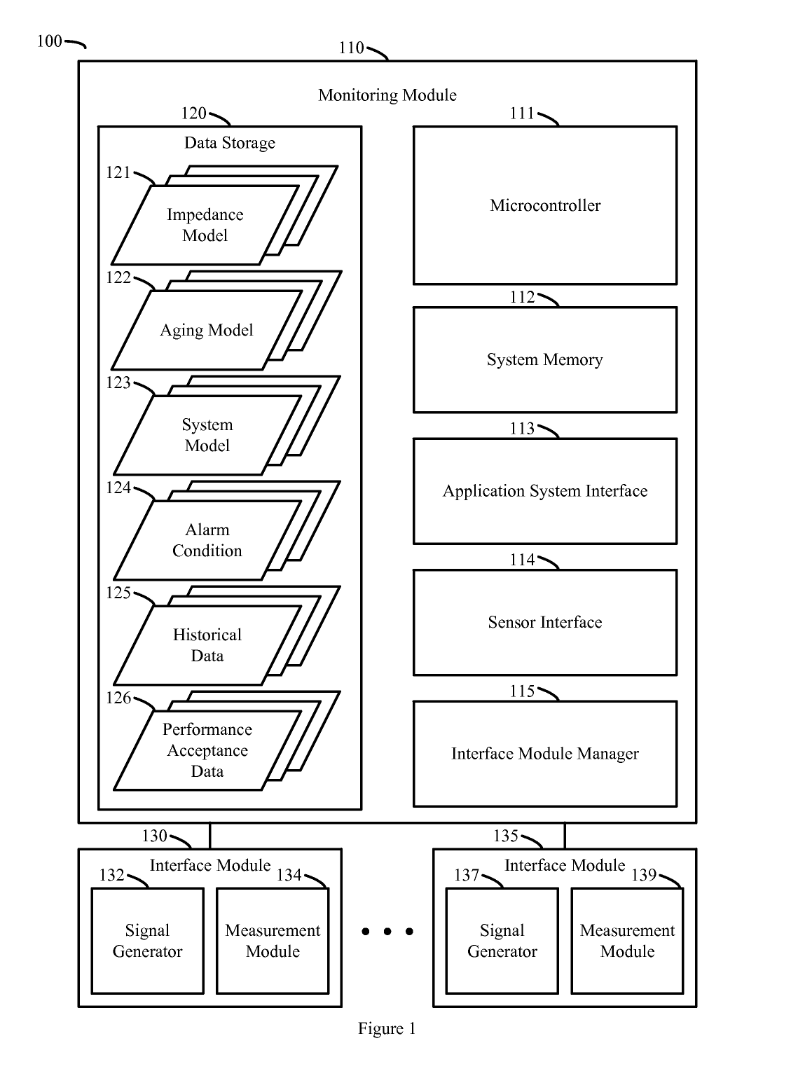

FIG. 1 shows an apparatus 100 for operational monitoring of electrochemical capacitors in accordance with the present invention. The apparatus 100 is most commonly embodied in a combination of functional electrical circuits and general purpose electronics capable of running microcode stored in local memory. The modular design of apparatus 100 in the block diagram of FIG. 1 is intended to organize the functional components in a manner that would be intuitive to one of ordinary skill in the art for implementation in an electronic device. In one embodiment, the elements of apparatus 100 would be embodied in semiconductor, printed circuit, and/or discrete electrical components attached to or integrated on a common printed circuit board. In an alternate embodiment, one or more elements could be implemented on a separate circuit board or in a package and interconnected through direct wiring or attachment to a common bus. One or more elements may also be instantiated solely in software running on a general purpose processing platform. Those of ordinary skill in the art will readily understand the cost, flexibility, and limitations of various configurations of hardware and software for implementing apparatus 100 for any given set of electrochemical capacitors, pack design, or intended application system. In addition, the separation of functions among the elements may be influenced by such design choices. The separation of functions into modules in FIG. 1 (and others) is a mere abstraction for the convenience of communication and should not be viewed as structurally limiting when implementing apparatus 100 in electronics and code.

The apparatus 100 includes a monitoring module 110. The monitoring module 110 contains the data and logic to oversee the operational monitoring process and output the real-time monitoring data generated by the monitoring process. The monitoring module 110 generates real-time monitoring data based on interrogation of the electrochemical capacitor cells it is monitoring for electrochemical impedance data. Based on the electrochemical impedance data from the interrogation of each cell, monitoring module 110 processes the impedance data using logic and additional data from an electrochemical impedance model for the cells being monitored. This generates further data correlating to the state of health for the capacitors being monitored and is used to generate a real-time output signal that may include alarms, alerts, or direct output of the state of health information and/or underlying data.

In the embodiment shown, the monitoring module 110 uses a microcontroller 111 and system memory 112 to run microcode embodied in non-volatile system memory or read from data storage 120. In one embodiment, microcontroller 111, system memory 112, and data storage 120 are a packaged general purpose data processing system for mobile or distributed computing solutions. In some embodiments, any or all of the microcontroller 111, system memory 112, and data storage 120 are shared with other subsystems of the onboard electronics of an electrochemical capacitor pack or an application system or one of its components.

The monitoring module 110 is also responsible for interacting with other systems, modules, and components. It includes an application system interface 113 that handles interactions with the application system using the apparatus 100. The application system interface 113 is electrically connected to the application system and may include both the power connection to the capacitor cells and a data connection that allows the monitoring module to access application system information and share monitoring information. In alternate configurations, the application system interface 113 includes only the power connection and has electronics necessary to detect the load condition of the application system from the power connection. No data connection to the application system is necessary and the output of the real-time monitoring data is made directly to the user (through an interface associated with the data processing system, simple LED indicator, or similar arrangement). In another configuration, the power connection is made directly between the application system and capacitors in the pack, but a data interface between the application system interface 113 and the application system provides load and/or other application system information and receives real-time monitoring data over the data interface. The application system interface 113 should be configured to receive or extract an operating system status signal that provides system load information, such as full-load, partial load, and no load conditions of the application system. With this information available, the electrochemical impedance models 121 may include an index for application system load correlated to the operating status signal that is used for evaluating the impedance data.

The monitoring module 110 also includes a sensor interface 114. The sensor interface 114 allows the monitoring module 110 to gather environmental data, such as temperature at one or more locations associated with the capacitor cells, for use in calculating real-time monitoring data and evaluating alert conditions. Use of the sensor interface 114 to sense temperature is provided by way of example only. Any number of additional sensor interfaces could be provided for gathering environmental condition data that relates to capacitor performance or failure modes, such as temperature, moisture, vibration, chemical levels, etc.

The monitoring module 110 also includes an interface module manager 115. The interface module manager 115 controls the interface and data exchange with each of the electrochemical cells that the apparatus is monitoring. The interface module manager 115 is responsible for cell discovery and organizing data received from the cells according to cell location for use in generating real-time monitoring data and evaluating alert conditions. In the embodiment shown, the interface module manager 115 communicates with a plurality of interface models 130, 135. The number of interface modules 130, 135 is generally equal to the number of electrochemical capacitor cells being monitored. Interface module manager 115 manages communication with each of the interface modules 130, 135 and provides the resulting data to the other components of the monitoring module 110.

Data storage 120 stores a plurality of data structures for use by the monitoring module 110. Data storage 120 may be configured to specific cell-types, pack configurations, and applications systems. Alternatively, it may be produced with a complete set of cell-types, pack configurations, and application systems such that it is universal across products and monitoring module 110 uses a set of settings to define the data to be used in operation.

In the embodiment shown, data storage 120 includes a plurality of impedance models 121. An impedance model is a set of frequency, voltage, and current values (amplitude and phase shift) with expected parameters based on the electrochemical capacitor cell and other data inputs, such as system load, temperature, aging, and historical data. It may also include specific equations and transfer functions for calculating and comparing these values, although, ideally more computation heavy aspects of the model are calculated in a laboratory setting and converted into constants or simplified functions for a limited set of operational variables likely to be encountered in operation. These values are highly dependent on the specific electrochemical inductance spectroscopy approach being used. In one embodiment, the electrochemical cells are characterized using EIS techniques to establish a reaction mechanism and determining kinetic parameters of a known, or at least commonly assumed, mechanism in a particular cell configuration. Some transient techniques may be used because they are well suited for extracting kinetic parameters when the mass transport is tedious. Several of these techniques may be used in generating any particular model, narrowing down any discrepancy between predicted and actual values until a simplified or parameter-based method of evaluating real-time inductance data can be developed. When complex heterogeneous reactions interact with mass transport, as occurs in many electrochemical capacitor cell configurations, time analysis of the transients will lead to very poor results in trying to extract a reaction mechanism, and a frequency analysis becomes more efficient. In one embodiment, selective use of frequency analysis provides an efficient means of comparing modeled impedance against measured impedance. This electrochemical impedance model defines a plurality of frequency domains correlating to a normal impedance curve for each of the capacitors. The model further identifies a specific frequency domain of interest selected from the domains along the curve. The domain selected may be based on a variety of cell, pack, system, environmental, or operational characteristics determined through modeling or experimentation. The selected frequency domain is then used to interrogate the cells and the impedance differential is compared against values from the normal impedance curve in the frequency domain of interest to determine the state of health for each of the plurality of capacitors. The selected frequency domain may also be used to drive the interrogation of the cells so that the monitoring signals are efficiently targeted only at the domain of interested. For example, the scope of inductance measurements may vary from 10−5 Hz to 10+11 Hz but then be targeted to specific frequency domains within that range depending the information spectrum being sought after.

In the embodiment shown, data storage 120 includes a plurality of aging models 122. An aging model takes a basic impedance curve modeled for a specific electrochemical capacitor cell in accordance with impedance models 121 and extrapolates how that impedance model changes over time. A non-linear system analysis algorithm is used for the majority of aging measurements. When an interface in the electrochemical capacitor is perturbed from its equilibrium by means of an external energy source, a permanent flow of charge and matter appears in it. By modeling the aging process and measuring against predicted changes we can detect: i) the existence of electrochemical reactions allowing the electric charge transfer between the electronic conductor (metal or semi-conductor) electrode and the ionic conductor (liquid or solid electrolyte) and ii) the gradients of electric and chemical potentials which make possible the transport of the reacting species between the bulk of the electrolyte and the interfacial reaction zone. These factors can be analyzed to accurately reflect the state of health of the capacitor and create parameterized aging models 122 for use in monitoring operating state of health of an electrochemical capacitor cell.

In the embodiment shown, data storage 120 includes a plurality of system models 123. A system model takes the system level configuration of elements and provides a schema for evaluating aggregate system performance. A system model starts with the number and positions of cells in a pack being monitored and the load and performance criteria of the application system. The system models 123 allow aggregation of the individual cell state of health information based on impedance models 121 and aging models 122 and assembles them into an holistic view of pack performance and impact on the system. For example, performance decay in certain positions (center versus end positions or a location with greater environmental stress) in the pack may be more or less “normal” and may warrant different responses. Temperature and environmental conditions detected through sensor interface 114 may also come into play in the system models 123, particularly where sensor data is generalized to the pack as opposed to provided on a cell position basis. For example, a change in impedance may be a normal response to certain temperature changes common in the application system environment, but may raise serious state of health issues if it occurs in the absence of the environmental change.

Apparatus 100 and, more specifically, the logic in system memory 112 may be customized and available for each electrochemical cell technology present in the application system. In one embodiment, the cell discovery process may be implemented at the cell level and communicate with system level components and logic that will integrate cell data across the array with system status information to monitor data and calculate alarm conditions.

In the embodiment shown, data storage 120 includes a plurality of alarm conditions 124. Alarm conditions 124 define the parameters under which an alarm should be output by monitoring module 110. For example, when the impedance of a particular cell decays at a rate greater than that predicted by the impedance model and the aging model, an alert status may be set and output to a user interface, remote monitoring facility, or the application system. Alarm conditions 124 would include a threshold value or range in which such an alert status should be set. Setting an alert status may trigger the output of a variety of real-time and historical data that would allow the recipient to understand the reason for the alert and the present condition of the cell, pack, or application system. In the alternative, an alert status simply notifies another system or user of a potential problem and then enables that system or user to query data storage 120 for whatever information might be useful for validation, diagnosis, or repair. The specific aging and performance algorithms are based on accumulated scientific knowledge, test results, and field data regarding electrochemical cells conditions. The selection of the parameters to interpret and the thresholds, relationships, and system factors that contribute to alarm conditions are customized for each electrochemical cell technology and, potentially the application and/or user preferences. Further levels of status data aggregation, remote communication, and integration into application level fault monitoring systems are also possible.

In the embodiment shown, data storage 120 includes historical data 125. Historical data 125 may include either or both of the measured data received through the interface module manager 115 or calculated data resulting from processing measured data in accordance with impedance models 121, aging models 122, and system models 123. Historical data 125 may be accessible only to monitoring module 110 or may include an interface for allowing remote systems to query the data.

In the embodiment shown, data storage 120 includes performance acceptance data 126. Performance acceptance data 126 defines the application system expectations regarding the performance of electrochemical capacitor cells and packs. This data may be used in generating the thresholds for alarm conditions 124. Performance acceptance data 126 may also include a log for recording performance of the monitored cells or pack with respect to the application system's requirements, such as power delivered, discharge and recharge rates, and the like. Note that this data may not be generated from the impedance-based interrogation of cells and may instead be supplemented by data received through the application system interface.

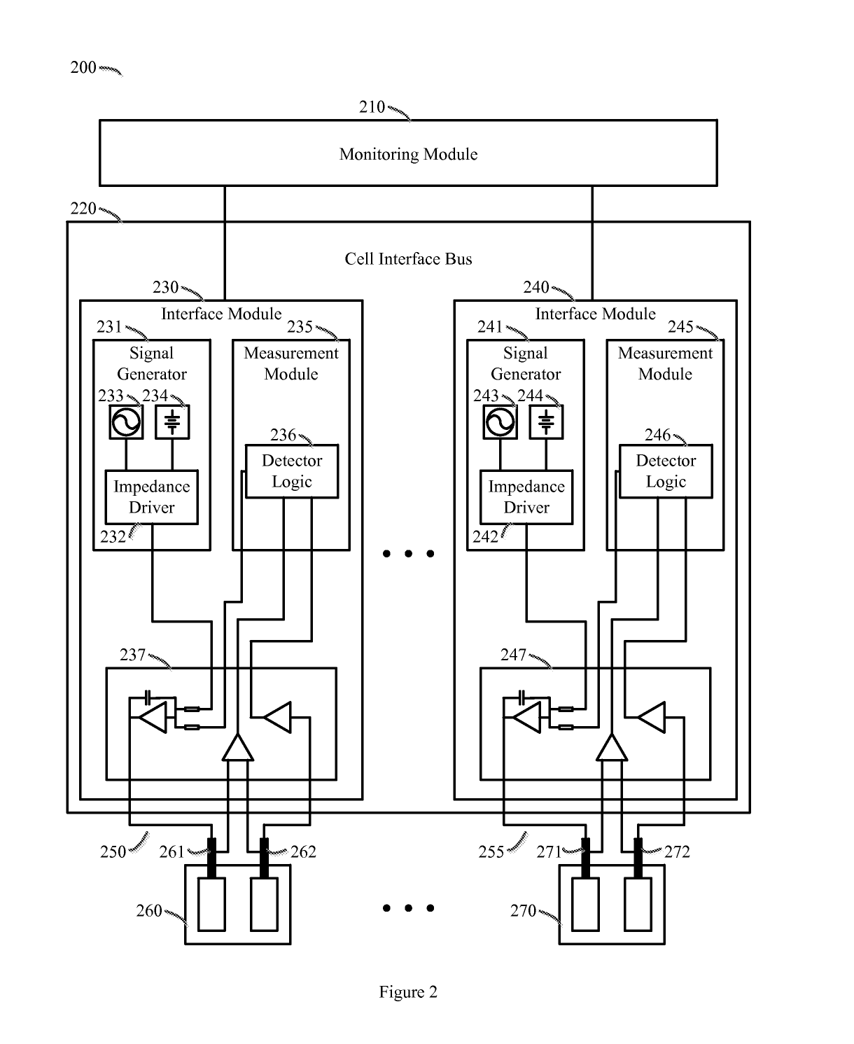

The monitoring module 110 relies on a plurality of interface modules 130, 135 for interrogating individual electrochemical capacitor cells. Each of the interface modules 130, 135 are electrically connected to monitoring module 110 for the transfer of a measurement signal representing the real-time impedance data measured from the cells being monitored. FIG. 1 shows two such interface modules 130, 135, but it will be understood that any number of interface modules could be present dependent on the number of cells being monitored. For example an energy storage pack with 32 electrochemical capacitor cells would have 32 interface modules to interrogate each of the cells on a one-to-one basis. The upper limit on interface modules is entirely dependent on processing power and interconnect architecture for electrically connecting to each of the cells and monitoring module 110. Interconnect to the cells being monitored is shown in FIG. 2.

Each interface module 130, 135 includes a signal generator 132, 137 and a measurement module 134, 139. Inductance measurements are conducted by applying voltage to the electrode interface of the connected cell and measuring the amplitude and the phase shift of the resulting current. The ratio of the output signal to the input perturbation is called the transfer function. If the input signal is the current and the output signal the voltage, the transfer function is the system impedance. If the input signal is the voltage and the output signal is the current, the transfer function is the system admittance, Y. Impedance, admittance, dielectric modulus, the complex dielectric constant (or dielectric permittivity) and the susceptibility, can all be derived from impedance spectroscopy. Signal generators 132, 137 are responsible for generating the applied voltage for the measurement, which may be referred to as the input monitor signal. Measurement modules 134, 139 are responsible for receiving the resulting current signal, which may be referred to as the output monitoring signal, measuring the amplitude and phase shift, and calculating the differential from the input monitoring signal to the output monitoring signal. The resulting measurement signal is then passed from the interface modules 130, 135 to monitoring module 110.

FIG. 2 shows an apparatus 200 for operational monitoring of electrochemical capacitors, providing greater detail regarding the cell interface architecture and terminal interconnects. Monitoring module 210 is a system for receiving an impedance measurement signal and generating and outputting an alert status based upon comparison to an impedance model and may operate in accordance with the monitoring module 110 in FIG. 1.

Apparatus 200 uses a cell interface bus 220 to manage the interconnects between monitoring module 210 and interface modules 230, 240. As discussed with regard to FIG. 1, apparatus 200 may include any number of interface modules 230, 240 as appropriate to the number of cells being monitored. Where that number is large and/or variable, the use of a bus architecture with interface modules embodied on separate cards or in separate packages with pin or similar electrical interfaces may be advantageous. Cell interface bus 220 may provide both power and data connections between interface cards 230, 240 and monitoring module 210.

Interface modules 230, 240 include signal generators 231, 241, measurement modules 234, 245, and impedance buffers 237, 247. As discussed with regard to FIG. 1, signal generators 231, 241 generate the input monitoring signals for interrogating electrochemical capacitor cells 260, 270 and measurement modules 235, 245 receive output monitoring signals from cells 260, 270 and generate an impedance measurement signal for communication to monitoring module 210. In order to make impedance measurements in real-time, while cells 260, 270 may be actively operating under an application system load across their terminals, interface modules 230, 240 use impedance buffers 237, 247 to organize four electrical interconnects to cells 260, 270, as well as a reference signal from signal generators 231, 241 to measurement modules 235, 245. The four terminals 250, 255 of each interface module 230, 240 connect to the two terminals of cells 260, 270, creating a four terminal evaluation system. Each interface module 230, 249 in apparatus 200 has four connections for the cells it is connected to. Each cell has four connections, two are the plus and minus for power, the second two are for the sense, measuring the differential voltage. The system will continuously recalibrate itself to the application of which it is part. It knows when the system is under load, partial or full and of course when no-load exists. It is important to have this instantaneous information in order to correctly evaluate electron/ion mobility and concentration within the cells.

Signal generators 231, 241 generate the output monitoring signal to drive measurement of the impedance of cells 260, 270. Signal generators 231, 241 include a DC load balancing circuit 233 and a DC power source 234 connected to impedance drivers 237, 247. In one embodiment, impedance drivers 232, 242 are programmable and enable interface modules 230, 240 to set the voltage, current, frequency, and/or other characteristics of the output monitoring signal. The interface module 230 may receive instructions from monitoring module 210 to program impedance drivers 232, 242 with a frequency range of interest for generating measurement data that can be evaluated against a particular domain of an impedance model. The output monitoring signal passes through impedance buffers 237, 247 to interrogate cells 260, 270 with a power signal and provide a separate baseline signal to measurement modules 235, 245 to use in calculating impedance.

Measurement modules 235, 245 receive a baseline signal from signal generators 231, 241, the power signal passing through the cells 260, 270, and a sense signal measuring the differential voltage between the terminals of cells 260, 270. Detector logic 236, 246 acts as potentiostat and/or galvanostat logic for measuring the amplitude and phase shift between the output monitoring signal and input monitoring signal. Detector logic 236, 246 uses the amplitude and phase shift for calculating the impedance of the cells 260, 270.

Impedance buffers 237, 247 provide the logic for taking the output monitoring signal from the signal generators 231, 247 and the three inputs needed by the measurement modules 235, 245 and providing a four lead system for connecting to the terminals 261, 262, 271, 272 of cells 260, 270. For example, four leads 250 connect to the positive terminal 261 and negative terminal 262 of cell 260. Positive terminal 261 receives two lead connections, a first lead for power and a second lead for sense, from interface module 230. Negative terminal 262 receives two other lead connections, a third lead for power and a fourth lead for sense, from interface module 230. Another set of four leads 255 connect to the positive terminal 271 and negative terminal 272 to cell 270.

Electrochemical capacitor cells 260, 270 may be any type of electrochemical capacitor with a two terminal interconnect system (positive terminals 261, 271 and negative terminals 262, 272). For example, cells 260, 270 could be electrolytic capacitors or electric double-layer capacitors (ELDCs, also known as supercapacitors or ultracapacitors) in a cylindrical or prismatic form factor. Cells 260, 270 need not be the same types, sizes, or configurations of cells. The separate interface modules 230, 240 allow the signals for interrogating cells 260, 270 to be matched to the particular cell configuration and monitoring module 210 can store the impedance, aging, and system models and logic for evaluating each cell separately, then aggregating that information for the processing of alarm conditions and performance acceptance.

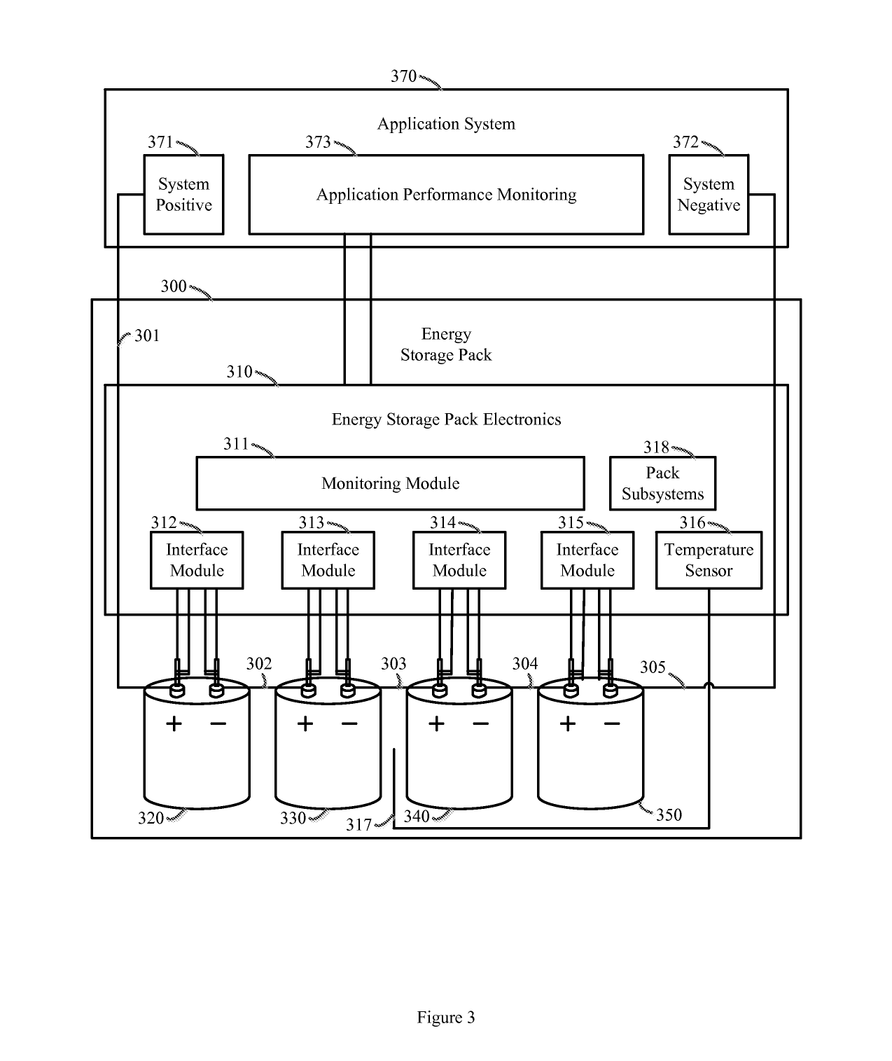

FIG. 3 shows an energy storage pack 300 incorporating an apparatus for monitoring capacitors integrated in energy storage pack electronics 310 and four capacitor cells 320, 330, 340, 350. Energy storage pack 300 is electrically connected to an application system 370. FIG. 3 demonstrates an example embodiment of an integrated system for collective monitoring of energy performance, an Electrochemical Energy Performance Monitoring System (EEPMS). EEPMS is EIS applied testing in a monitoring system for manufactured products and, more specifically, on many individual cells in series and or parallel connected as a system.

Energy storage pack 300 is a packaged energy storage module with a manufacturer defined energy storage profile in terms of capacitance and voltage available to the application system in which it is integrated, such as applications system 370. Energy storage pack 300 is a smart storage system that includes active onboard electronics in addition to passive cell interconnect wiring. Power interconnects 301, 302, 303, 304, 205 provide the power connection between application system 370 and electrochemical capacitor cells 320, 330, 340, 350.

Energy storage pack 300 includes energy storage pack electronics 310 to provide additional signal and data processing capabilities. In one embodiment, energy storage pack electronic 310 provides a data bus and a power bus for integrating additional functional electronic subcomponents for operation and communication. Energy storage pack electronics 310 include a monitoring module 311, an interface module 312, 313, 314, 315 for each cell 320, 330, 340, 350, a temperature sensor 316, and other pack subsystems 318. Monitoring module 311 may be configured as described above for monitoring module 110 in FIG. 1. Interface modules 312, 313, 314, 315 may be configured as described above for interface modules 230, 240 in FIG. 2 and provide four lead interconnects to cells 320, 330, 340, 350.

Temperature sensor 316 is an example of an environmental sensor that can be included in energy storage electronics 310 and provide real-time environmental data to monitoring module 312. Temperature sensor 316 may include both interface electronics for onboard integration and a remote thermistor probe 317 that can be placed strategically within the configuration of cells 320, 330, 340, 350. In an alternate embodiment, a plurality of temperature sensors or other environmental condition sensors provide environmental information from multiple locations in energy storage pack 300.

Pack subsystems 318 may include other onboard electronic subsystems for energy storage pack 300. For example, energy storage pack 300 could integrate motor controllers or other application-specific features, emergency interrupts, interface components (screen, LEDs, input devices, etc.), and communication channels for accessing the data bus (ports, wireless, etc.).

Application system 370 may be any type of application system integrating an energy storage pack based on electrochemical capacitors. For example, a large wind turbine using an energy storage pack for emergency blade positioning, an electric vehicle or vehicle subsystem with burst power needs, or communication system with capacitor-based emergency power reset/restart. Application system 370 includes system positive 371 and system negative 372 for power connection to electrochemical capacitor cells 320, 330, 340, 350 in energy storage pack 300. Application system 370 includes application performance monitoring subsystem 373, a data or signal driven subsystem for monitoring the operational performance and/or failure modes of application system 370 and its energy components, such as energy storage pack 300. Application performance monitoring subsystem 373 is electrically connected to energy storage pack 300 to provide application state information to energy storage pack 300 and receive real-time monitoring data output from energy storage pack 300. Application performance monitoring system 373 may include both power and data channels for supporting integration of the cell monitoring and other subsystems of energy storage pack 310. Application performance monitoring subsystem 373 may, in turn, communicate with a larger performance monitoring system, such as a system for monitoring an entire installation of windmills or a network of commonly owned or operated devices, some or all of which may include similar energy storage packs with onboard monitoring apparatus.

FIG. 4 shows a method 400 of operational monitoring of capacitors using electrochemical impedance. Method 400 may be implemented by a system or apparatus, such as those described above with regard to FIGS. 1-3. In step 410, an input signal is generated for monitoring one or more electrochemical capacitors. In one embodiment, the input monitoring signal is a voltage intended to stimulate the electrochemical interfaces in the electrochemical capacitor and enable an inductance measurement. In step 420, an output signal is received from the electrochemical capacitor that was interrogated with the input monitoring signal. In one embodiment, the output monitoring signal contains current information, such as amplitude and phase shift, that can be used with the input monitoring signal to calculate impedance of the electrochemical cell. In step 430, an impedance differential between the input monitoring signal and the output monitoring signal is calculated. In step 440, the calculated impedance differential is compared to an impedance model for the electrochemical cell to generate real-time monitoring data, such as alarm conditions based on desired performance acceptance criteria and impedance model parameters known to correlate to the desired performance. In step 450, selected monitoring data is output to a user or other system. For example, an alert condition may be triggered and communicated to a host application system or trigger a user output like illuminating an LED. Monitoring data may also include real-time and historical data stored by the monitoring apparatus and available for querying as part of a monitoring routine or in response to an alert. In the embodiment shown, the impedance model used for generating the real-time monitoring data is queried in step 460. Step 460 may occur, as shown, prior to generation of the input signal is step 410 in order to allow the signal to be customized to parameters of interest in the specific impedance model, such as a selected frequency domain. In the embodiment shown, application status information may also be received from a host application system in step 470. Application system status, such as load status, may be indexed in the impedance model or otherwise factored into calculation and analysis of monitoring data.

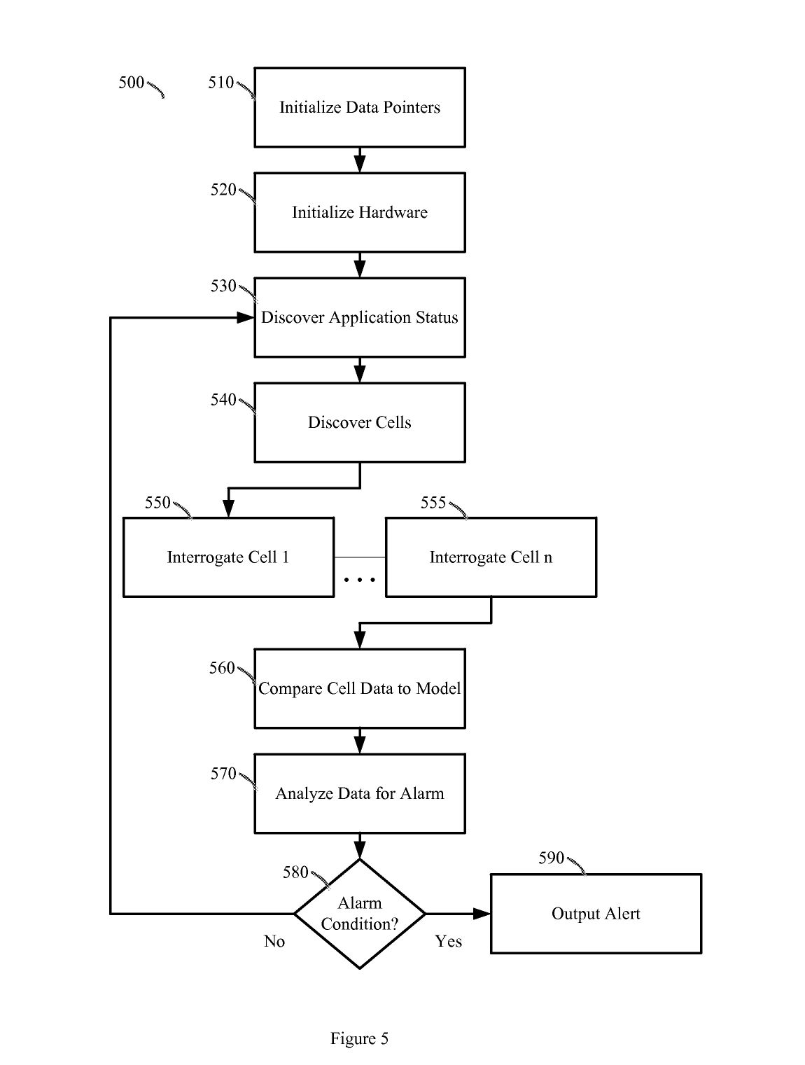

FIG. 5 is a flow chart of a process 500 for generating and outputting real-time monitoring data for operational monitoring, such as the operational monitoring of FIG. 4. Process 500 may be implemented by a system or apparatus, such as those described above with regard to FIGS. 1-3. In step 510, the monitoring system initializes data pointers. In step 520, the monitoring system initializes hardware. In step 530, the monitoring system discovers application status, such as the load condition for the application system. In step 540, the monitoring system discovers the cells attached to the monitoring system. Steps 550, 555 represent a plurality of calls to interrogate each cell from 1 to n that is attached to the monitoring system to measure its impedance. In step 560, the monitoring system compares the impedance data from the interrogation of the cells to an impedance model. In step 570, the monitoring system analyzes the data for alarm conditions based on the comparison of cell impedance data to the impedance model for parameters of interest. In step 580, the monitoring system determines whether the calculated parameters meet or exceed a threshold value for an alarm condition. If yes, in step 590, an alert condition is set and output by the monitoring system to a user interface or another monitoring system. If no, an alert condition is not set and the monitoring system returns to step 530 to discover application status and proceed through the process again.

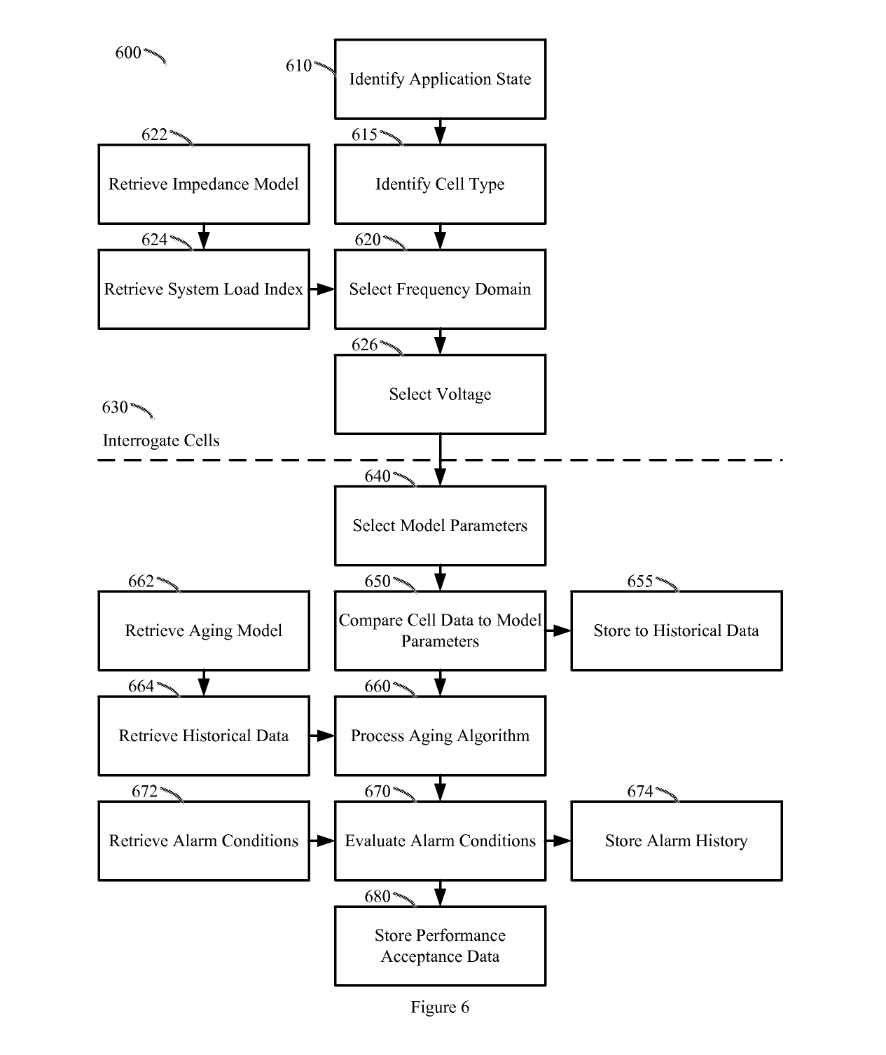

FIG. 6 shows a process 600 for the microprocessor, system memory, and data storage of a monitoring system engaged in operational monitoring of capacitors, such as the operational monitoring of FIG. 4. Process 600 may be implemented by a system or apparatus, such as those described above with regard to FIGS. 1-3. In step 610, an application state is identified and placed in system memory based on data received from an application system. In step 615, a cell type is identified from a system model in data storage and placed in system memory. In step 620, a frequency domain is selected and put into system memory. In some embodiments, an impedance model is retrieved from data storage in step 622 and a system load index is retrieved from data storage in step 622 and a lookup table in data storage enables the cell type and application state to be used to determine the frequency domain selected in step 620. In step 626, a voltage value is selected and put into system memory. The voltage value may be determined from a default value or indexed in a manner similar to the frequency domain selection. The voltage and frequency values can then be read from system memory by one or more interface modules and used in the interrogation if individual cells (630). Once interrogation is complete and real-time cell impedance data is placed in system memory, the process continues. In step 640, impedance model parameters are read from data storage and placed into system memory In step 650, real-time cell impedance data is compared against the impedance model parameters and, in step 655 both measured and calculated values are stored to a historical data repository in data storage. In step 660, results of comparing the real-time cell impedance data against the impedance model parameters is further processed against one or more aging algorithms. In one embodiment, processing of aging algorithms is enabled by retrieving an aging model from data storage and retrieve applicable historical data from data storage. The aging model, historical data, and current data are then used to process a time-based analysis of impedance change in step 660. In step 670, alarm conditions are loaded into system memory for evaluation against the impedance comparisons calculated in the preceding steps. The alarm conditions are generally stored in data storage and retrieved from data storage in step 672. Evaluation of the alarm conditions may conditionally trigger alert-based output. In step 674, the evaluation of the alarm condition is stored in an alarm history in the data storage. In step 680, performance acceptance data is written to the data storage if the monitored cells continue to operate within acceptable performance ranges according to the impedance calculations.

The foregoing embodiments are provided as examples only. Other embodiments of the invention will be apparent to those of ordinary skill in the art.

1. An apparatus for monitoring operational characteristics of a plurality of capacitors in an application system, comprising:
a monitoring signal generator for generating an input monitoring signal for each of the plurality of capacitors;
a measurement module for receiving an output monitoring signal for each of the plurality of capacitors in response to the input monitoring signal and generating a measurement signal representing an impedance differential between the input monitoring signal and the output monitoring signal;
an electrochemical impedance model for the plurality of capacitors whereby the measurement signal is compared to the electrochemical impedance model to determine a state of health;
a monitoring module for generating and outputting real-time monitoring data correlating to the state of health for the plurality of capacitors from the measurement signal and the electrochemical impedance model.

2. The apparatus of claim 1, further comprising:
a system interface module electrically connected to the application system to receive an operating status signal related to the application system use of the plurality of capacitors;
wherein the electrochemical impedance model further includes an index for application system load correlated to the operating status signal; and
wherein the monitoring module uses the operating status signal for generating the real-time monitoring data.

3. The apparatus of claim 2, wherein real-time monitoring data provides state of health information for the plurality of capacitors under full-load, partial load, and no load conditions of the application system.

4. The apparatus of claim 1, wherein each of the plurality of capacitors has a positive terminal and a negative terminal and the monitoring signal generator is electrically connected by a first lead and a second lead to the positive terminal and by a third lead and a fourth lead to the negative terminal.

5. The apparatus of claim 4, wherein the monitoring signal generator and the measurement module are integrated into a plurality of interface modules wherein each of the plurality of capacitors has a corresponding interface module from the plurality of interface modules and each of the plurality of capacitors is electrically connected to the corresponding interface module by a first interface lead and a second interface lead connected to the positive terminal and a third interface lead and a fourth interface lead connected to the negative terminal.

6. The apparatus of claim 5, wherein the plurality of interface modules each further comprise impedance buffers for managing current flow through each of the plurality of capacitors to enable accurate calculation of impedance for each of the plurality of capacitors.

7. The apparatus of claim 1, wherein the electrochemical impedance model defines a plurality of frequency domains correlating to a normal impedance curve for each of the plurality of capacitors and wherein the differential between the input monitoring signal and the measurement signal is compared against the normal impedance curve in a frequency domain of interest to determine the state of health for each of the plurality of capacitors.

8. The apparatus of claim 7, wherein the monitoring module selects the frequency domain of interest from the plurality of frequency domains and commands the monitoring signal generator to generate input monitoring signals corresponding to a waveform in the frequency domain of interest.

9. The apparatus of claim 1, further comprising:
a temperature sensor electrically connected to the monitoring module to receive a temperature signal related to the thermal state of the plurality of capacitors;
wherein the electrochemical impedance model further includes an index for thermal state correlated to the temperature signal; and
wherein the monitoring module uses the temperature signal for generating the real-time monitoring data.

10. The apparatus of claim 1, wherein the plurality of capacitors comprise cells in energy storage pack and the apparatus of claim 1 is integrated into the energy storage pack for installation into the application system.

11. The apparatus of claim 1, wherein the monitoring module includes a data storage subsystem that includes data selected from historical signal data, historical calculated data, a plurality of electrochemical impedance models, a plurality of capacitor aging algorithms, performance acceptance data, and alarm condition alert status.

12. The apparatus of claim 11, wherein outputting the real-time monitoring data includes selectively outputting an alert status based on an evaluation of alarm conditions.

13. A method for monitoring operational characteristics of a plurality of capacitors in an application system, comprising the steps of:
generating an input monitoring signal for each of the plurality of capacitors;
receiving an output monitoring signal for each of the plurality of capacitors in response to the input monitoring signal;
generating a measurement signal by calculating an impedance differential between the input monitoring signal and the output monitoring signal;
generating real-time monitoring data by comparing the impedance differential to an electrochemical impedance model for the plurality of capacitors to determine a state of health of the plurality of capacitors;
outputting the real-time monitoring data correlating to the state of health for the plurality of capacitors.

14. The method of claim 13, further comprising the step of receiving an operating status signal related to the application system use of the plurality of capacitors and wherein the electrochemical impedance model further includes an index for application system load correlated to the operating status signal for use in generating the real-time monitoring data.

15. The method of claim 14, wherein real-time monitoring data provides state of health information for the plurality of capacitors under full-load, partial load, and no load conditions of the application system.

16. The method of claim 13, wherein the electrochemical impedance model defines a plurality of frequency domains correlating to a normal impedance curve for each of the plurality of capacitors and wherein the differential between the input monitoring signal and the measurement signal is compared against the normal impedance curve in a frequency domain of interest to determine the state of health for each of the plurality of capacitors.

17. The method of claim 16, further comprising the step of selecting the frequency domain of interest from the plurality of frequency domains and wherein the step of generating the input monitoring signal generates the input monitoring signal corresponding to a waveform in the frequency domain of interest.

18. The method of claim 13, further comprising the step of receiving a temperature signal related to the thermal state of the plurality of capacitors and wherein the electrochemical impedance model further includes an index for thermal state correlated to the temperature signal used for generating the real-time monitoring data.

19. The method of claim 13, wherein the real-time monitoring data is calculated from data selected from historical signal data, historical calculated data, a plurality of electrochemical impedance models, a plurality of capacitor aging algorithms, performance acceptance data, and alarm condition alert status.

20. The method of claim 19, wherein the step of outputting the real-time monitoring data includes selectively outputting an alert status based on an evaluation of alarm conditions.

21. A energy storage pack comprising:
a plurality of capacitors;
a monitoring signal generator for generating an input monitoring signal for each of the plurality of capacitors;
a measurement module for receiving an output monitoring signal for each of the plurality of capacitors in response to the input monitoring signal and generating a measurement signal representing an impedance differential between the input monitoring signal and the output monitoring signal;
an electrochemical impedance model for the plurality of capacitors whereby the measurement signal is compared to the electrochemical impedance model to determine a state of health;
a monitoring module for generating and outputting real-time monitoring data correlating to the state of health for the plurality of capacitors from the measurement signal and the electrochemical impedance model.
